(19) United States
(12) Patent Application Publication
(10) Pub. No.: US 2009/0126979 A1
(43) Pub. Date: May 21, 2009

(54) SEMICONDUCTOR PACKAGE CIRCUIT BOARD AND METHOD OF FORMING THE SAME

(75) Inventors: Ka-Eun CHAE, Chungcheongnam-do (KR); Wang-Jae LEE, Chungcheongnam-do (KR); Yong-Jin JUNG, Chungcheongnam-do (KR); Kun-Ho SONG, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/270,591

(22) Filed: Nov. 13, 2008

(30) Foreign Application Priority Data
Nov. 21, 2007 (KR) 2007-0119300

(51) Int. Cl. H05K 1/02; H05K 3/00; G02B 5/12

(52) U.S. Cl. 174/257; 29/829; 359/515

(57) ABSTRACT

A semiconductor package circuit board has an indicator for specifying a location of a defective circuit board unit. The semiconductor package circuit board includes circuit board units arranged in an m-by-n matrix pattern. The indicator has marking areas arranged in an m-by-n matrix pattern so that the marking areas are marked in correspondence to locations of identified defective circuit board units of the circuit board units. An operator can readily put a defective mark on the indicator without any confusion. The operator or a sensor can readily recognize the defective mark. Since the indicator can be formed on the circuit board unit, the integration of the semiconductor package circuit board can be increased, and the productivity can be substantially improved. Furthermore, a pathway of the sensor can be reduced, and interferences that might occur if the sensor moves can be hindered.

### CROSS-REFERENCE TO RELATED PATENT APPLICATIONS

This application claims the benefit of Korean Patent Application No. 10-2007-0119300, filed on Nov. 21, 2007, in the Korean Intellectual Property Office, the disclosure of which is incorporated herein in its entirety by reference.

### BACKGROUND OF THE INVENTION

1. Field of the Invention

The present invention relates to a semiconductor package circuit board having an indicator for specifying a location of a defective circuit board unit, a method of forming a semiconductor package circuit board, and an indicator for specifying a location of a defective circuit board unit.

2. Description of the Related Art

A semiconductor package circuit board is an element of a semiconductor package. Typically, semiconductor chips are mounted on and supported by the semiconductor package circuit board. Electric signals processed in the semiconductor chips flow through the semiconductor package circuit board to external devices via various electric signal transferring members, such as balls, pins, and leads, attached to one or both surfaces of the semiconductor package circuit board.

Conventionally, a semiconductor package circuit board is divided into a plurality of semiconductor package circuit board units arranged in a matrix pattern in order to perform a batching process, specifically, in order to perform a semiconductor chip mounting or wiring process through a batching process.

A semiconductor package circuit board can be manufactured using various methods. For example, an epoxy resin layer or a resin layer is formed using a film or a tape. Then a metal film is coated on one or both surfaces of the epoxy resin layer or the resin layer. A conductive circuit pattern is formed in the metal film using a photo technique or an etching technique. A protective layer is coated on the conductive circuit pattern, thereby completing the manufacturing process of a semiconductor package circuit board.

The semiconductor package circuit board thus manufactured is inspected using a surface identification test or a function test to find any defective semiconductor package circuit board unit. If a defective semiconductor package circuit board unit is found, the location of the defective semiconductor package circuit board unit is marked with ink. Then an apparatus for performing a subsequent process recognizes the marked location and does not perform a corresponding process with respect to the defective semiconductor package circuit board unit.

However, the identification of the marked location is so difficult that operators often make a mistake.

### SUMMARY OF THE INVENTION

The present invention provides a semiconductor package circuit board having an indicator for specifying a location of a defective circuit board unit, a method of forming a semiconductor package circuit board having an indicator, and an indicator for specifying a location of a defective circuit board unit, wherein the indicator has marking areas arranged in an m-by-n matrix pattern corresponding to an m-by-n matrix pattern of the circuit board units so that an operator may readily mark a location of a defective circuit board unit in the corresponding marking area.

The present invention also provides a semiconductor package circuit board having an indicator for specifying a location of a defective circuit board unit, a method of forming a semiconductor package circuit board having an indicator, and an indicator for specifying a location of a defective circuit board unit, wherein the indicator is formed on a dummy unit or a defective circuit board unit in the circuit board units arranged in a matrix pattern. Thus, the integration of the semiconductor package circuit board is more increased than in cases where the indicator is formed outside the matrix pattern of the circuit board units. Furthermore, the productivity can be substantially increased.

The present invention also provides a semiconductor package circuit board having an indicator for specifying a location of a defective circuit board unit, a method of forming a semiconductor package circuit board having an indicator, and an indicator for specifying a location of a defective circuit board unit, wherein defective marks are not dispersed and are put only within an m-by-n matrix pattern. Thus, a pathway of a sensor for detecting the indicator can be minimized. Interferences which might occur if the sensor moves can be prevented, and a travel time of the sensor is substantially zero.

According to an aspect of the present invention, there is provided a semiconductor package circuit board for readily marking a location of a defective circuit board unit. The semiconductor package circuit board includes a plurality of circuit board units arranged in an m-by-n matrix and an indicator having marking areas arranged in an m-by-n matrix so that a location of an identified defective circuit board unit is readily marked in the corresponding marking area of the indicator.

The size of the indicator may be substantially equal to or smaller than each circuit board unit. The indicator may be formed on a dummy unit fixed at a column a and a row b in the matrix pattern of the circuit board units or on one of identified defective circuit board units.

The marking areas are unmarked areas, which are to be marked with a defective mark. The unmarked areas may have a reflective surface to allow reflection of light. The reflective surface of the unmarked areas may be formed of the same metallic material as a metallic material of a metallic circuit layer on the circuit board units so that the reflective surface of the unmarked areas and the metallic circuit layer of the circuit board units are formed at the same time.

In addition, an area of the indicator other than the unmarked areas may be formed by a dark opaque coating layer.

The indicator may have marking areas on one surface and a glue layer on the other surface.

According to another aspect of the present invention, there is provided is a method of forming a semiconductor package circuit board having an indicator for specifying a location of a defective circuit board unit. The method includes arranging a plurality of circuit board units in an m-by-n matrix pattern and forming an indicator including marking areas arranged in an m-by-n matrix pattern in correspondence to the m-by-n matrix pattern of the circuit board units.

The indicator and the circuit board units may be formed at the same time. Alternatively, the indicator may be attached to a defective unit in the circuit board units.

According to another aspect of the present invention, there is provided an indicator for specifying a location of a defective circuit board unit. The indicator includes marking areas arranged in an m-by-n matrix pattern corresponding to a plurality of circuit board units arranged in an m-by-n matrix pattern.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of a semiconductor package circuit board having indicators for specifying a location of a defective circuit board unit, according to an embodiment of the present invention, wherein each of the indicators is formed on a dummy unit having a dummy mark indicating its location;

FIG. 2 is a plan view of a work area S in the semiconductor package circuit board shown in FIG. 1.

FIG. 3 is a plan view of the work area S in the semiconductor package circuit board shown in FIG. 1, wherein the indicator has a dummy mark and defective marks;

FIG. 4 is a plan view of a portion of a semiconductor package circuit board before an indicator for specifying a location of a defective circuit board unit according to another embodiment of the present invention is attached to the semiconductor package circuit board;

FIG. 5 is a plan view of the semiconductor package circuit board of FIG. 4 after the indicator has been attached to the semiconductor package circuit board; and

FIG. 6 is a perspective view of the semiconductor package circuit board of FIG. 4, the indicator of FIG. 5, and a method of forming the semiconductor package circuit board.

### DETAILED DESCRIPTION OF THE INVENTION

A semiconductor package circuit board having an indicator for specifying a location of a defective circuit board unit, a method of forming a semiconductor package circuit board having an indicator, and an indicator for specifying a location of a defective circuit board unit will now be described more fully with reference to the accompanying drawings, in which exemplary embodiments of the invention are shown.

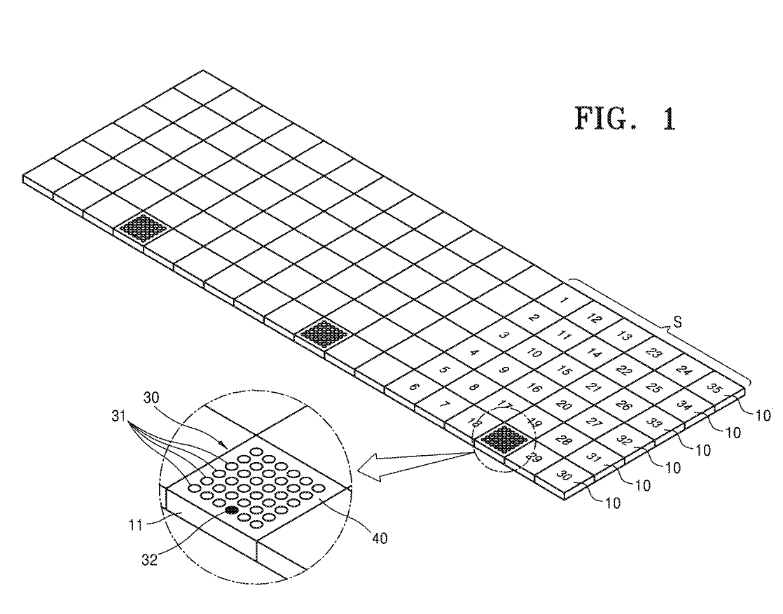

As illustrated in FIG. 1, a semiconductor package circuit board has indicators 30 for specifying locations of defective circuit board units, according to an embodiment of the present invention. The semiconductor package circuit board includes a plurality of circuit board units 10 arranged in m×n matrix patterns. The circuit board units 10 include dummy units 11. Specifically, the indicators 30 are formed on the dummy units 11. Each of the dummy units 11 is fixed at a specific location of a column a and a row b in the m×n matrix pattern of the circuit board units 10.

As illustrated in FIG. 1, according to an embodiment of the present invention, a six-by-six sub-matrix, for example, defines a first work area S. The sub-matrix includes a dummy unit 11 and other thirty-five (35) circuit board units 10. Semiconductor chips (now shown) are mounted and wired on the circuit board units 10 by a mounting and wiring apparatus. The mounting and wiring apparatus has a sensor (not shown) attached to a side of the apparatus for detecting the indicator 30. When the mounting and wiring apparatus moves over the first work area S, the sensor does not move from the location of the dummy unit 11 because the dummy unit 11 is fixed at the column a and the row b in the matrix pattern of the circuit board units 10.

Because the sensor is fixed in the mounting and wiring apparatus, interferences which might occur if the sensor moves can be prevented, and a travel time of the sensor is substantially reduced as compared to conventional cases.

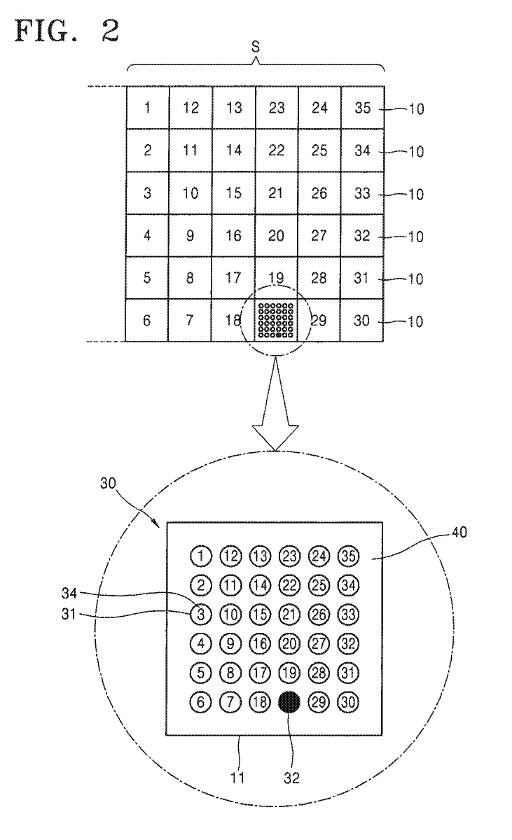

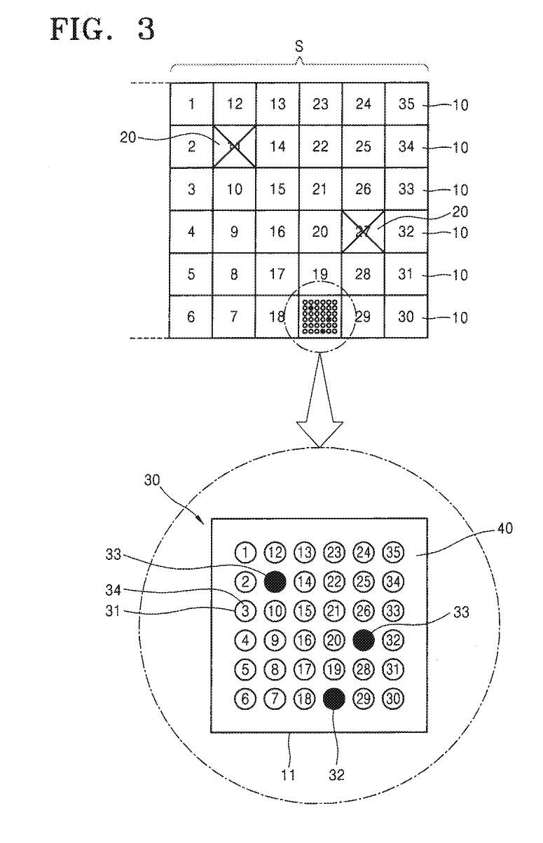

Meanwhile, each of the indicators 30, as illustrated in FIG. 1, includes marking areas 31 (each represented by a circle in FIG. 2) arranged in an m-by-n matrix pattern. Therefore, the marking areas 31 can be marked with a marker such as a marking material in correspondence to locations of identified defective circuit board units (see 20 of FIG. 3) in the circuit board units 10.

Referring to FIGS. 1 and 2, the circuit board units 10 are numbered from 1 to 35, and the marking areas 31 of the indicator 30 are numbered from 1 to 35 in correspondence to the circuit board units 10. That is, the circuit board units 10 are arranged in the m-by-n matrix pattern, and the marking areas 31 are also arranged in the m-by-n matrix pattern.

In practice, to prevent operators' confusion, these numbers can be marked in the circuit board units 10 or in the marking areas 31 of the indicator 30. In some cases, various signals may be used to specify the circuit board units 10 or the marking areas 31 of the indicator 30.

However, even when those numbers or signals are not used, operators can readily specify the locations of defective circuit board units because the locations of the circuit board units 10 respectively correspond to the locations of the marking areas 31 in the indicator 30. For example, an operator memorizes the location of a defective circuit board unit at the second column and the second row and then readily marks one of the marking areas 31 in the indicator 30 which corresponds to the location of the defective circuit board unit.

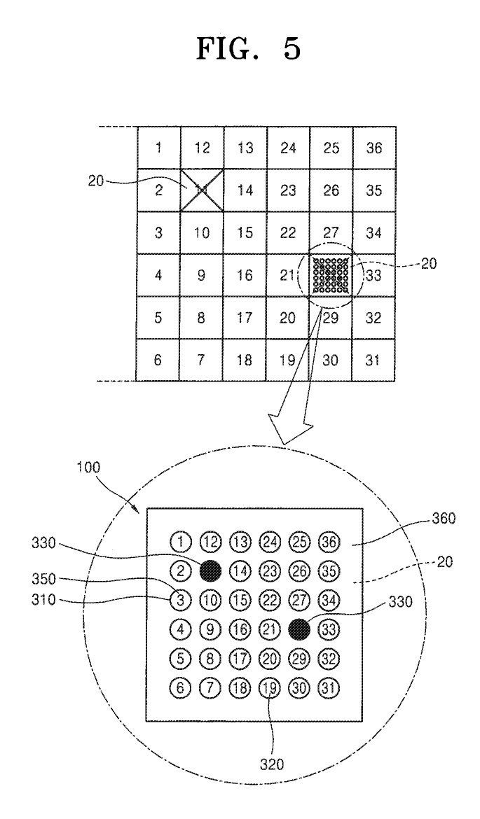

Meanwhile, the size of the indicator 30, as illustrated in FIGS. 1 and 2, may be substantially equal to or smaller than that of each circuit board unit 10 so that the indicator 30 is formed on the dummy unit 11, which has the same size as each circuit board unit 10, or on one of the defective circuit board units 20 as shown in FIG. 5.

Alternatively, the size of the indicator 30 may be greater than the size of each circuit board unit 10. In such a case, the indicator 30 may be disposed on a bottom surface of the semiconductor package circuit board or on a separate carrier frame (not shown) used to deliver the semiconductor package circuit board. However, the number of circuit board units 10 which can be processed at the same time in a work area S of a predetermined apparatus is reduced, so that the productivity may be degraded.

When the indicator 30 is formed on the dummy unit 11 at the column a and the row b, as illustrated in FIGS. 1 and 2, the indicator 30 may have a marking area marked with a dummy mark 32 at a column a and a row b so that a subsequent process is not performed on the dummy unit 11.

Meanwhile, as illustrated in FIG. 3, the marking areas 31 of the indicator 30 may be unmarked areas 34 so that those areas can be marked with a defective mark 33 using marker ink.

The unmarked areas 34 each have a reflective surface that reflects light. The reflective surface may be formed of the same metallic material as a metallic material forming a metallic circuit layer of the circuit board units 10. In such a case, the unmarked areas 34 and the metallic circuit layer of the circuit board units 10 can be formed at the same time. For example, the unmarked areas 34 may be formed of Al, Au, Ag, Cu, Ni, or an alloy thereof.

By simultaneously forming the metallic circuit layer of the circuit board units 10 and the unmarked areas 34, the manufacturing costs can be substantially reduced.

In some cases, the unmarked areas 34 may have, for example, a white, yellow, or fluorescent surface.

Furthermore, the indicator 30 may include a dark opaque coating layer 40 formed on a portion of the indicator 30 other than the unmarked areas 34.

The dark opaque coating layer 40 of the indicator 30 may be formed of the same material as a material forming a surface protective coating layer of the semiconductor package circuit board. In such a case, the dark opaque coating layer 40 and the surface protecting coating layer of the circuit board units 10 can be formed at the same time. Therefore, the manufacturing costs can be substantially reduced.

When a defective circuit board unit 20 is located at a column x and a row y in the matrix pattern of the circuit board units 10, an unmarked marking area 34 located at a column x and a row y in the matrix pattern of the indicator 30 is marked in correspondence to the location of the defective circuit board unit 20. For example, as illustrated in FIG. 3, an operator memorizes the locations of defective circuit board units 20 with Nos. 11 and 27 (represented by “X” thereon in FIG. 3.), which are at the second column and the second row and at the fifth column and the fourth row, respectively. Then, the operator may readily mark corresponding unmarked areas 34 of the indicator 30 with use of a marker such as a writing material.

The defective marks 33 shown in FIG. 3 may be put on the marking areas 31 together with the dummy mark 32. An apparatus for performing a subsequent process may not perform its due process on the defective circuit board units 20 corresponding to the defective marks 33 and the dummy unit 11 corresponding to the dummy mark 32.

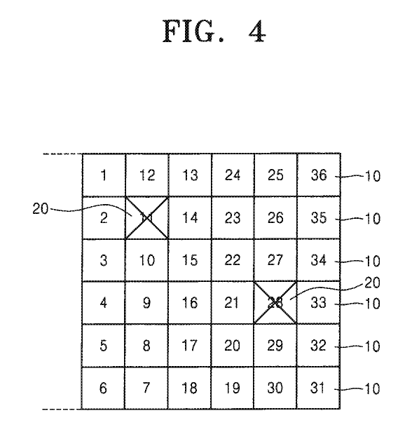

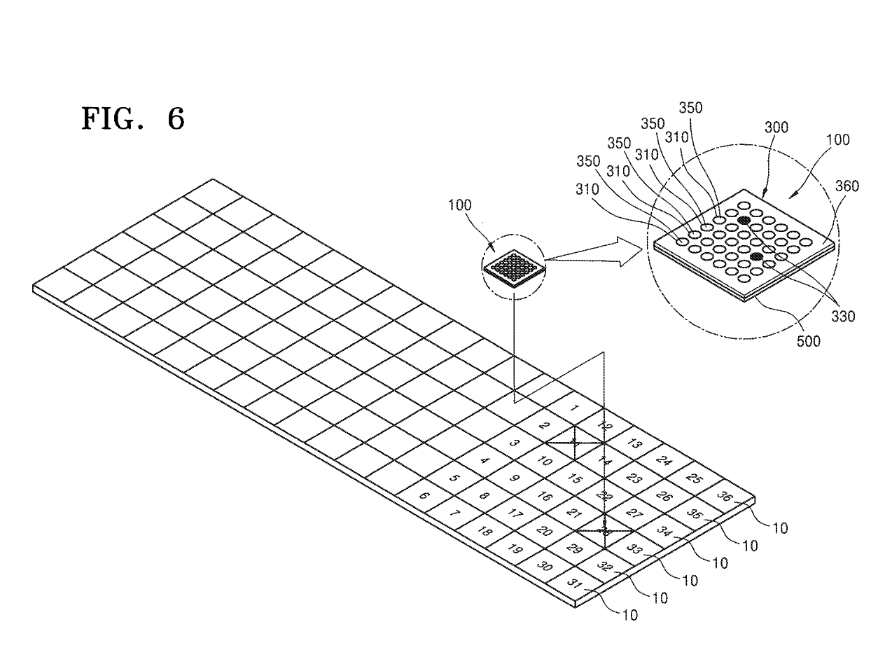

Meanwhile, as illustrated in FIGS. 4-6, the present invention also provides an indicator 100 for specifying a location of a defective circuit board unit on one surface. The indicator 100 includes marking areas 310 arranged in an m-by-n matrix pattern corresponding to a m-by-n matrix pattern of a plurality of circuit board units 10.

Specifically, each of the marking areas 310 in the indicator 100 may be formed by a bright portion 350. An area of the indicator 100 other than the bright portion 350 may be formed by a dark portion 360. Thus, a sensor for detecting the indicator 100 may recognize dark ink marked on the bright portion 350.

Alternatively, although not illustrated in the drawings, each of the marking areas 310 may be formed by a dark portion, and an area of the indicator 100 other than the marking areas 310 may be formed by a bright portion. In this case, a sensor for detecting the indicator 100 may recognize bright ink marked on the dark portion.

Furthermore, the indicator 100 for specifying a location of a defective circuit board unit may have the marking areas 310 printed on one surface of the indicator 100 and a glue layer 500 formed on the opposed surface. With this configuration, when an operator finds a defective circuit board unit 20 with the indicator 100 in his/her hands, he/she may mark a marking area 310 of the indicator 100 corresponding to the location of the found defective circuit board unit 20 with a marker. Then the indicator 100 may be attached to the defective circuit board unit 20. A method of forming a semiconductor package circuit board with an indicator for specifying a location of a defective circuit board unit according to the present invention includes forming a plurality of circuit board units 10 arranged in an m-by-n matrix pattern and forming an indicator 30 on the circuit board unit 10. The indicator 30 has a plurality of marking areas 31 arranged in an m-by-n matrix pattern corresponding to the m-by-n matrix pattern of the circuit board units 10.

In this regard, the indicator 30 and the circuit board units 10 can be formed at the same time. Alternatively, the circuit board units 10 may be manufactured separately, and the indicator 30 may be attached to one of identified defective circuit board units 20 in the circuit board units 10.

Meanwhile, the indicator 30 may also be formed on other locations, that is, on a separate carrier frame (not shown) used to carry the semiconductor package circuit board.

As described above, according to the embodiments of the present invention, an operator can readily put a defective mark on an indicator without any confusion, and the operator or a sensor can readily recognize the defective mark on the indicator. In addition, since the indicator can be positioned on the semiconductor package circuit board, the integration of the semiconductor package circuit board can be increased, and the productivity can be substantially improved. Furthermore, a pathway of the sensor can be reduced, and interferences that might occur if the sensor moves can be hindered. Thus, a travel time of the sensor is substantially reduced as compared to conventional cases.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package circuit board comprising:
a plurality of circuit board units arranged in a matrix pattern having columns and rows; and
an indicator formed on one of the circuit board units, the indicator including a plurality of marking areas for specifying a location of a defective circuit board unit of the circuit board units, the marking areas being arranged in a matrix pattern corresponding to the matrix pattern of the circuit board units.

2. The semiconductor package circuit board of claim 1, wherein the indicator has a size substantially equal to or smaller than that of each circuit board unit.

3. The semiconductor package circuit board of claim 1, wherein the circuit board units includes a dummy unit located at a column a and a row b in the matrix pattern of the circuit board units, and the indicator is formed on the dummy unit.

4. The semiconductor package circuit board of claim 3, wherein the matrix pattern of the indicator includes a marked marking area located at a column a and a row b corresponding to the column a and the row b in the matrix pattern of the circuit board units.

5. The semiconductor package circuit board of claim 1, wherein the indicator is formed on a defective circuit board unit of the circuit board units.

6. The semiconductor package circuit board of claim 1, wherein the matrix pattern of the indicator includes a marked marking area located at a column x and a row y corresponding to a location of a defective circuit board unit at a column x and a row y in the matrix pattern of the circuit board units.

7. The semiconductor package circuit board of claim 1, wherein the unmarked marking areas have a reflective surface to reflect light.

8. The semiconductor package circuit board of claim 7, wherein the circuit board units include a metallic circuit layer formed of a metallic material, and the reflective surface of the unmarked marking areas is formed of the same material as the metallic material of the metallic circuit layer.

9. The semiconductor package circuit board of claim 8, wherein the reflective surface is formed of Al, Au, Ag, Cu, Ni, or an alloy thereof.

10. The semiconductor package circuit board of claim 1, wherein the unmarked marking areas have a bright surface.

11. The semiconductor package circuit board of claim 1, wherein the indicator includes a dark coating layer formed in an area other than the marking areas.

12. The semiconductor package circuit board of claim 11, wherein the circuit board units include a surface protective coating layer formed of a protective coating material, and the dark coating layer of the indicator is formed of the same material as the protective coating material of the surface protective coating layer.

13. A method of forming a semiconductor package circuit board with an indicator for specifying a location of a defective circuit board unit, the method comprising:
forming a plurality of circuit board units arranged in a matrix pattern; and
forming an indicator on one of the circuit board units, the indicator including a plurality of marking areas arranged in a matrix pattern corresponding to the matrix pattern of the circuit board units.

14. The method of claim 13, wherein the plurality of circuit board units and the indicator are simultaneously formed.

15. The method of claim 13, wherein the forming the indicator comprises attaching the indicator to a defective circuit board unit of the circuit board units.

16. The method of claim 13, wherein the forming the indicator comprises attaching the indicator to a portion adjacent the circuit board units.

17. The method of claim 16, wherein the portion adjacent the circuit board units comprises a carrier frame used to carry the semiconductor package circuit board.

18. An indicator comprising:
a plurality of marking areas for specifying a location of a defective circuit board unit in a plurality of circuit board units arranged in a matrix pattern, the marking areas being arranged in a matrix pattern corresponding to the matrix pattern of the circuit board units.

19. The indicator of claim 18, comprising:
a bright portion in the marking areas; and
a dark portion in an area other than the marking areas.

20. The indicator of claim 18, comprising a glue layer formed on an opposed surface to a surface on which the marking areas are formed.
